(19) United States
(12) Patent Application Publication
(10) Pub. No.: US 2012/0190219 A1
(43) Pub. Date: Jul. 26, 2012

(54) MOTHERBOARD AND MEMORY CONNECTOR THEREOF

(75) Inventors: Yu-Chang PAI, Tu-Cheng (TW); Yung-Chieh CHEN, Tu-Cheng (TW)

(73) Assignee: HON HAI PRECISION INDUSTRY CO., LTD., Tu-Cheng (TW)

(21) Appl. No.: 13/033,608

(22) Filed: Feb. 24, 2011

(30) Foreign Application Priority Data
Jan. 20, 2011 (TW) 100102049

(51) Int. Cl. H05K 1/00

(52) U.S. Cl. 439/65

(57) ABSTRACT

A motherboard includes a printed circuit board (PCB) and a memory connector. A number of golden fingers are set on corresponding sides of a top layer and a bottom layer of the PCB and connected to a memory controller. First and second socket slots are defined in two opposite sides of the memory connector. A number of grooves are defined in top and bottom sidewalls bounding the first and the second socket slots. A number of metal pins are exposed through the grooves of the first socket slot for connection to the golden fingers of the PCB. The metal pins are extended to the second socket slot to be exposed through the grooves of the second socket opening for connection to the golden fingers of a memory.

### BACKGROUND

1. Technical Field

The present disclosure relates to a motherboard and a memory connector of the motherboard.

2. Description of Related Art

In some notebook computers, memory chips are soldered on motherboards to reduce the thickness. However, the memory capacity for these notebook computers cannot be changed. In other notebook computers, the memory chips are not soldered onto the motherboard but are inserted into sockets that allow the memory chips to be almost stacked on the motherboard. However, the memory chips or sockets still increase the height of the motherboard. Therefore there is room for improvement in the art.

### BRIEF DESCRIPTION OF THE DRAWINGS

Many aspects of the embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the several views.

FIG. 1 is an exploded, isometric view of a motherboard in accordance with an exemplary embodiment of the present disclosure.

FIG. 2 is an assembled, isometric view of the motherboard of FIG. 1.

FIG. 3 is a cross-sectional view of the motherboard of FIG. 2.

### DETAILED DESCRIPTION

The disclosure, including the drawings, is illustrated by way of example and not by limitation. It should be noted that references to “an” or “one” embodiment in this disclosure are not necessarily to the same embodiment, and such references mean at least one.

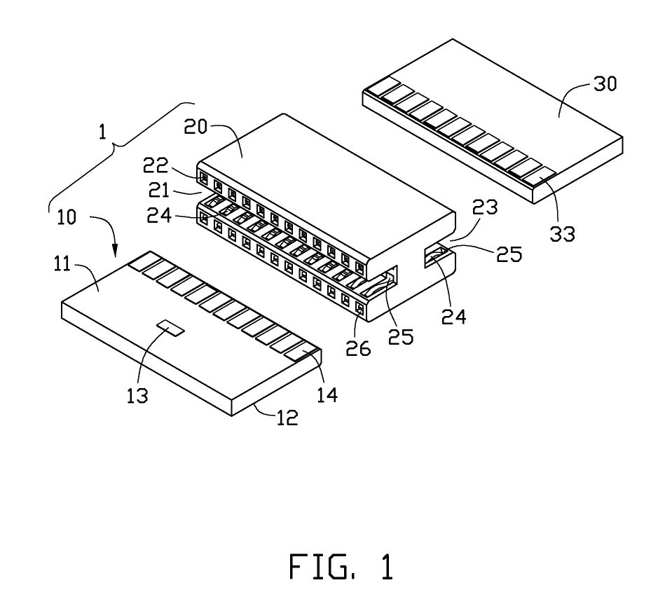

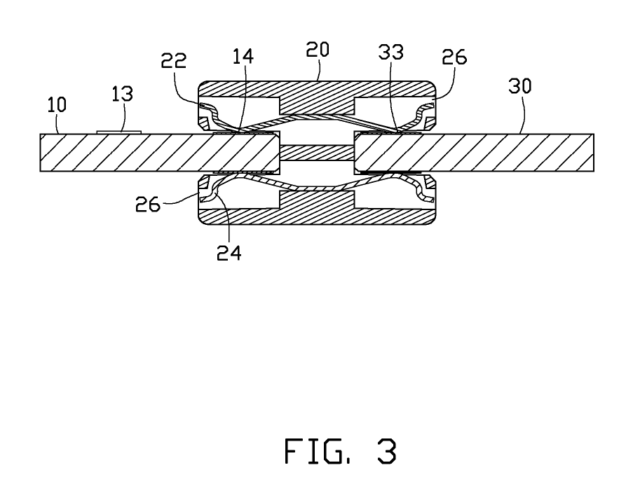

Referring to FIG. 1 and FIG. 3, a motherboard 1 in accordance with an exemplary embodiment includes a printed circuit board (PCB) 10 and a memory connector 20. The PCB 10 includes a top layer 11 and a bottom layer 12. Other layers of the PCB 10 between the top layer 11 and the bottom layer 12 are not shown. A plurality of golden fingers 14 is set on corresponding sides of the top layer 11 and the bottom layer 12. A memory controller 13 is set on the top layer 11. Other elements, such as a central processing unit socket (not shown) are set on the top layer 11. The golden fingers 14 are electrically connected to the memory controller 13.

The memory connector 20 is substantially H-shaped. Opposite sides of the memory connector 20 respectively define two socket slots 21 and 23, and a plurality of holes 26 is defined on opposite side surfaces of the memory connector 20, respectively at the top and the bottom sides of the socket slots 21 and 23. A plurality of grooves 25 is defined in the top and the bottom sidewalls bounding the socket slots 21 and 23, communicating with the holes 26. A plurality of metal pins 22 and 24 is exposed from the memory connector 20 through the grooves 25 of the socket slot 21, to be electrically connected to the golden fingers 14 of the top layer 11 and the bottom layer 12 of the PCB 10 when the PCB 10 is inserted in the socket slot 21. The grooves 25 of the socket slot 21 respectively communicate with the grooves 25 of the socket slot 23. The metal pins 22 and 24 are respectively extended to the socket slots 23 to be exposed through the grooves 25 of the socket slot 23, to be electrically connected to golden fingers 33 of a memory 30 when the memory 30 is inserted in the socket slot 23. The length of the socket slots 21 and 23 and the length of the memory connectors 20 are the same as length of the memory 30. The height of the socket slot 21 is equal to or slightly larger than thickness of the PCB 10, to receive the PCB 10. The height of the socket slot 23 is equal to or slightly larger than the thickness of the memory 30, to receive the memory 30. A number of the golden fingers 14 of the top layer 11 and the bottom layer 12 of the PCB 10 and a number of the metal pins 22 and 24 of the memory connector 20 are the same as a number of the golden fingers 33 of the memory 30. In one embodiment, the metal pins 22 and 24 are resilient metal pieces.

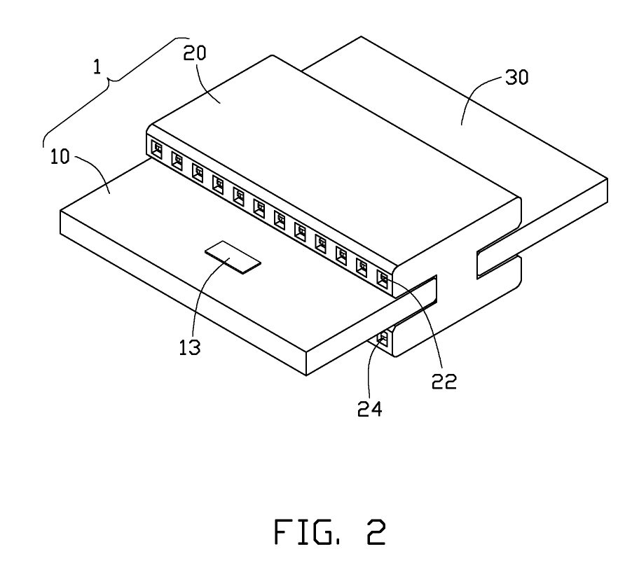

Referring to FIG. 2, when the PCB 10 is inserted into the socket slot 21, and the memory 30 is inserted into the socket slot 23. Due to the metal pins 22 and 24 of the memory connector 20 being respectively connected to the golden fingers 14 of the PCB 10, the memory controller 13 can communicate with the memory 30 through the golden fingers 14 and the memory connector 20. When the memory 30 is inserted in the socket slot 23 of the memory connector 20, the memory 30 is substantially coplanar with the PCB 10.

The height of the motherboard 1 will not be changed when the memory 30 is inserted in the memory connector 20, and the memory connector 20 can be removed from the PCB 10 conveniently.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A motherboard comprising:
a printed circuit board (PCB) comprising:
a top layer;
a bottom layer;
a memory controller set on the top layer; and
a plurality of golden fingers set on corresponding sides of the top layer and the bottom layer, electrically connected to the memory controller; and
a memory connector, wherein opposite sides of the memory connector respectively define a first socket slot and a second socket slot, top and bottom sidewalls bounding the first and the second socket slots respectively define a plurality of grooves, the grooves of the first socket slot respectively communicate with the grooves of the second socket slot, a plurality of metal pins is exposed from the grooves of the first socket slot, to be electrically connected to the golden fingers of the top layer and the bottom layer of the PCB when the PCB is inserted in the first socket slot, the plurality of metal pins is extended to the second socket slot to be exposed through the grooves of the second socket slot, to be electrically connected to golden fingers of a memory when the memory is inserted in the second socket slot to be coplanar with the PCB.

2. The motherboard as claimed in claim 1, wherein the memory connector is substantially H-shaped, lengths of the first and the second socket slots and a length of the memory connector are the same as a length of the memory, a height of the first socket slot is equal to or slightly larger than thickness of the PCB, a height of the second socket slot is equal to or slightly larger than thickness of the memory.

3. The motherboard as claimed in claim 1, wherein a number of the metal pins of the memory connector is the same as a number of golden fingers of the memory and a number of the golden fingers of the top layer and the bottom layer of the PCB.

4. The motherboard as claimed in claim 1, wherein the metal pins of the memory connector are resilient metal pieces.

5. A memory connector applicable to connect a memory to a printed circuit board (PCB), wherein opposite sides of the memory connector respectively define a first socket slot and a second socket slot, top and bottom sidewalls bounding the first and the second socket slots respectively define a plurality of grooves, the grooves of the first socket slot respectively communicate with the grooves of the second socket slot, a plurality of metal pins is exposed through the grooves of the first socket slot, to be electrically connected to golden fingers of a top layer and a bottom layer of the PCB when the PCB is inserted in the first socket slot, the plurality of metal pins is extended to the second socket slot to be exposed through the grooves of the second socket slot, to be electrically connected to golden fingers of a memory when the memory is inserted in the second socket slot.

6. The memory connector as claimed in claim 5, wherein the memory connector is substantially H-shaped, lengths of the first and the second socket slots and a length of the memory connector are the same as a length of the memory, a height of the first socket slot is equal to or slightly larger than thickness of the PCB, a height of the second socket slot is equal to or slightly larger than thickness of the memory.

7. The memory connector as claimed in claim 5, wherein a number of the metal pins of the memory connector is the same as a number of the golden fingers of the memory and a number of the golden fingers of the top layer and the bottom layer of the PCB.

8. The memory connector as claimed in claim 5, wherein the metal pins of the memory connector are resilient metal pieces.
